(19) United States
(12) Patent Application Publication
(10) Pub. No.: US 2026/0068506 A1
(43) Pub. Date: Mar. 5, 2026

(54) DISPLAY DEVICE AND ELECTRONIC DEVICE INCLUDING THE SAME

(71) Applicant: Samsung Display Co., Ltd., Yongin-si (KR)

(72) Inventors: Woong Sik KIM, Yongin-si (KR); Hyeong Gyu KIM, Yongin-si (KR); Dong Hwan BAE, Yongin-si (KR)

(21) Appl. No.: 19/319,328

(22) Filed: Sep. 4, 2025

(30) Foreign Application Priority Data
Sep. 5, 2024 (KR) 10-2024-0120971

(51) Int. Cl. H10K 59/80; H10K 59/122

(52) U.S. Cl. CPC H10K 59/879; H10K 59/122; H10K 59/80515

(57) ABSTRACT

A display device includes first and second anode electrodes spaced apart, a pixel-defining layer defining a second pixel opening overlapping a second exposed surface of the second anode electrode, and a first pixel opening overlapping a first exposed surface of the first anode electrode having a planar surface area that is greater than a planar surface area of the second exposed surface, a cathode electrode facing the first and second anode electrodes, an emission structure between the cathode electrode and the first and second exposed surfaces, and first and second lens structures above the cathode electrode, respectively overlapping the first and second anode electrodes, and having a trapezoidal shape in a sectional view in which a length of a top side is less than a length of a bottom side, a first thickness of the first lens structure being greater than a second thickness of the second lens structure.

### CROSS-REFERENCE TO RELATED APPLICATION

The present application claims priority to, and the benefit of, Korean Patent Application Number 10-2024-0120971, filed on Sep. 5, 2024, in the Korean Intellectual Property Office, the entire disclosure of which is incorporated herein by reference.

### BACKGROUND

### 1. Field

Various embodiments of the present disclosure relate to a display device and an electronic device including the same.

### 2. Description of Related Art

Display devices are used to display images. Such a display device may include a plurality of sub-pixels. Each of the sub-pixels may include at least one light-emitting element configured to generate light. If output efficiency of light generated from the light-emitting element is enhanced, display quality of the display device may be improved.

### SUMMARY

Various embodiments of the present disclosure are directed to a display device with improved display quality.

One or more embodiments of the present disclosure may provide a display device including a first anode electrode and a second anode electrode spaced apart from each other, a pixel-defining layer defining a second pixel opening overlapping a second exposed surface of the second anode electrode, and a first pixel opening overlapping a first exposed surface of the first anode electrode having a planar surface area that is greater than a planar surface area of the second exposed surface, a cathode electrode facing the first anode electrode and the second anode electrode, an emission structure between the cathode electrode and the first exposed surface and the second exposed surface, and a first lens structure and a second lens structure above the cathode electrode, respectively overlapping the first anode electrode and the second anode electrode, and having a trapezoidal shape in a sectional view in which a length of a top side is less than a length of a bottom side, a first thickness of the first lens structure being greater than a second thickness of the second lens structure in a sectional view.

Upper surfaces of the first lens structure and the second lens structure may be flat.

In a plan view, the upper surfaces of the first lens structure and the second lens structure may completely overlap the first exposed surface and the second exposed surface, respectively.

The first exposed surface and the second exposed surface may have a circular or N-sided polygonal shape in a plan view, N being a natural number of 4 or more.

The first lens structure and the second lens structure may have an M-sided polygonal shape in a plan view, M being equal to N.

The first lens structure and the second lens structure may have a substantially identical planar surface area.

The display device may further include a third anode electrode spaced apart from the first anode electrode and the second anode electrode, and a third lens structure above the cathode electrode to overlap the third anode electrode, and having a trapezoidal shape in which a length of a top side is less than a length of a bottom side in a sectional view, wherein the pixel-defining layer further defines a third pixel opening overlapping a third exposed surface of the third anode electrode.

The planar surface area of the second exposed surface may be substantially identical to a planar surface area of the third exposed surface, wherein the second thickness of the second lens structure is substantially identical to a third thickness of the third lens structure in a sectional view.

In a plan view, a first shortest distance between the first lens structure and the second lens structure, a second shortest distance between the first lens structure and the third lens structure, and a third shortest distance between the second lens structure and the third lens structure may be substantially identical.

The display device may further include a color filter layer between the cathode electrode and the first lens structure, the second lens structure, and the third lens structure.

The color filter layer may include a blue color filter overlapping the first exposed surface, a green color filter overlapping the second exposed surface, and a red color filter overlapping the third exposed surface.

A surface area of a side surface of the first lens structure may be greater than a surface area of a side surface of the second lens structure.

One or more embodiments of the present disclosure may provide a display device including a first anode electrode and a second anode electrode spaced apart from each other, a pixel-defining layer defining a second pixel opening overlapping a second exposed surface of the second anode electrode and a first pixel opening overlapping a first exposed surface of the first anode electrode having a planar surface area that is greater than a planar surface area of the second exposed surface, a cathode electrode facing the first anode electrode and the second anode electrode, an emission structure between the cathode electrode and the first exposed surface and the second exposed surface, a second lens structure above the cathode electrode, overlapping the second anode electrode, and having a trapezoidal shape in a sectional view in which a length of a top side is less than a length of a bottom side, and a first lens structure above the cathode electrode, overlapping the first anode electrode, and having a semicircular or semielliptical shape in a sectional view having a first thickness from a lower surface of the first lens structure to an uppermost point of the first lens structure that is greater than a second thickness of the second lens structure.

The first exposed surface and the second exposed surface may have a circular or N-sided polygonal shape in a plan view, N being a natural number of 4 or more.

The first lens structure may have a circular shape in a plan view, wherein the second lens structure has an M-sided polygonal shape in a plan view, M being equal to N.

The display device may further include a third anode electrode spaced apart from the first anode electrode and the second anode electrode, and a third lens structure above the cathode electrode to overlap the third anode electrode, and having a trapezoidal shape in which a length of a top side is less than a length of a bottom side in a sectional view, wherein the pixel-defining layer further defines a third pixel opening overlapping a third exposed surface of the third anode electrode.

The planar surface area of the second exposed surface may be substantially identical to a planar surface area of the third exposed surface, wherein the second thickness of the second lens structure is substantially identical to a third thickness of the third lens structure in a sectional view.

In a plan view, a first shortest distance between the first lens structure and the second lens structure, a second shortest distance between the first lens structure and the third lens structure, and a third shortest distance between the second lens structure and the third lens structure may be substantially identical.

The display device may further include a color filter layer between the cathode electrode and the first lens structure, the second lens structure, and the third lens structure.

The color filter layer may include a blue color filter overlapping the first exposed surface, a green color filter overlapping the second exposed surface, and a red color filter overlapping the third exposed surface.

One or more embodiments of the present disclosure may provide an electronic device including a processor to provide an image data, and a display device to display an image based on the image data, the display device including a first anode electrode and a second anode electrode spaced apart from each other, a pixel-defining layer defining a second pixel opening overlapping a second exposed surface of the second anode electrode, and a first pixel opening overlapping a first exposed surface of the first anode electrode having a planar surface area that is greater than a planar surface area of the second exposed surface, a cathode electrode facing the first anode electrode and the second anode electrode, an emission structure between the cathode electrode and the first exposed surface and the second exposed surface, and a first lens structure and a second lens structure above the cathode electrode, respectively overlapping the first anode electrode and the second anode electrode, and having a trapezoidal shape in a sectional view in which a length of a top side is less than a length of a bottom side, a first thickness of the first lens structure being greater than a second thickness of the second lens structure in a sectional view.

### BRIEF DESCRIPTION OF THE DRAWINGS

FIG. 1 is a block diagram for describing a display device in accordance with embodiments of the present disclosure.

FIG. 2 is a block diagram for describing any one sub-pixel among sub-pixels of FIG. 1.

FIG. 3 is a plan view for describing a display panel of FIG. 1.

FIGS. 4 and 5 are plan views for describing one or more embodiments of any one pixel included in the display panel of FIG. 3.

FIGS. 6A and 6B are sectional views taken along the line I1-I1′ of FIG. 5.

FIG. 7 is a diagram for describing one or more embodiments of an emission structure of FIG. 6A.

FIG. 8 is a diagram for describing one or more other embodiments of the emission structure of FIG. 6A.

FIGS. 9 to 11 are sectional views for describing first one or more embodiments of a method of fabricating a display device including the pixel of FIG. 6A.

FIGS. 12 and 13 are sectional views for describing second one or more embodiments of the method of fabricating the display device including the pixel of FIG. 6A.

FIGS. 14 to 18 are sectional views for describing third one or more embodiments of the method of fabricating the display device including the pixel of FIG. 6A.

FIGS. 19 to 22 are sectional views for describing fourth one or more embodiments of the method of fabricating the display device including the pixel of FIG. 6A.

FIGS. 23 and 24 are plan views for describing one or more other embodiments of any one pixel included in the display panel of FIG. 3.

FIG. 25 is a sectional view taken along the line I2-I2′ of FIG. 24.

FIGS. 26 and 27 are plan views for describing one or more other embodiments of any one pixel included in the display panel of FIG. 3.

FIG. 28 is a sectional view taken along the line I3-I3′ of FIG. 27.

FIG. 29 is a block diagram of an electronic device according to an embodiment.

FIG. 30 shows schematic views of various embodiments of an electronic device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like.

Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B.

Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the DR1-axis, the DR2-axis, and/or the DR3-axis are not limited to three axes of a rectangular coordinate system, and may be interpreted in a broader sense. For example, the DR1-axis, the DR2-axis, and the DR3-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

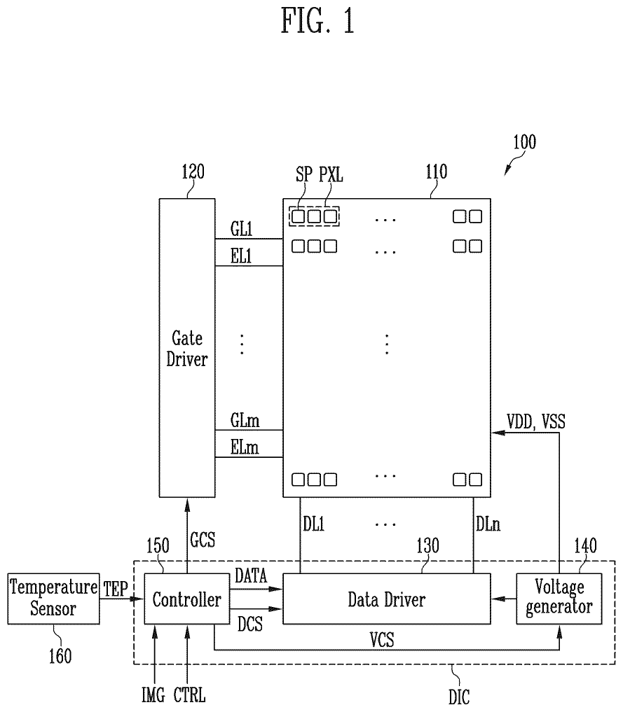

FIG. 1 is a block diagram for describing a display device 100 in accordance with embodiments of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn, wherein m n n are positive integers greater than 1.

Each of the sub-pixels SP may include at least one light-emitting element configured to generate light. Accordingly, each of the sub-pixels SP may generate light in a corresponding color, such as red, green, blue, cyan, magenta, or yellow. Two or more sub-pixels SP among the sub-pixels SP may form one pixel PXL. For example, as illustrated in FIG. 1, three sub-pixels SP may form one pixel PXL.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal for outputting gate signals in synchronization with a timing at which data signals are applied, and the like.

In embodiments, there may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be located on a first side of the display panel 110. However, the embodiments are not limited to the aforementioned example. For example, the gate driver 120 may be divided into two or more drivers that are physically and/or logically distinguished from each other. The drivers may be located on a first side of the display panel 110, and a second side of the display panel 110 opposite to the first side. As such, the gate driver 120 may be located around the display panel 110 in various configurations according to embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the associated sub-pixels SP may generate light corresponding to the data signals. As a result, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages, and to provide the generated voltages to components of the display device 100. For example, the voltage generator 140 may be configured to receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level that is lower than the first power voltage VDD. In other embodiments, the first power voltage VDD or the second power voltage VSS may be provided from an external device of the display device 100.

In addition, the voltage generator 140 may generate various voltages. For example, the voltage generator 140 may generate an initialization voltage to be applied to the sub-pixels SP. For example, during a sensing operation for sensing electrical characteristics of transistors and/or light-emitting elements of the sub-pixels SP, a corresponding reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and a voltage control signal VCS, in response to the control signal CTRL.

The controller 150 may convert the input image data IMG to be suitable for the display device 100 or the display panel 110, and then may output image data DATA. In embodiments, the controller 150 may align the input image data IMG to be suitable for the sub-pixels SP on a row basis and then output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separate from the driver integrated circuit DIC.

The display device 100 may include at least one temperature sensor 160. The temperature sensor 160 is configured to sense a peripheral temperature and to generate temperature data TEP indicating the sensed temperature. In embodiments, the temperature sensor 160 may be located adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control components, such as the data driver 130 and/or the voltage generator 140, thus adjusting data signals and the first and second power voltages VDD and VSS.

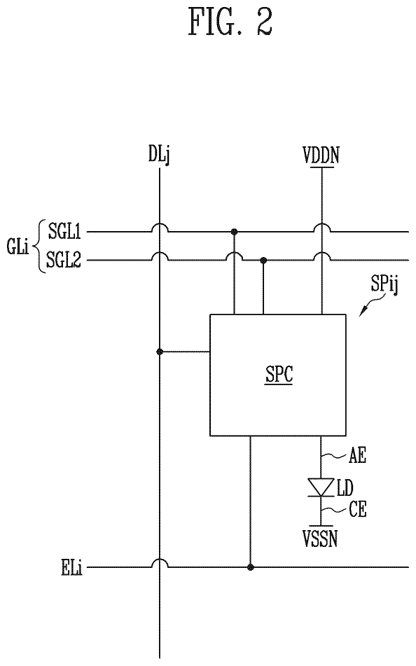

FIG. 2 is a block diagram for describing any one sub-pixel among the sub-pixels SP of FIG. 1. In FIG. 2, a sub-pixel SPij is illustrated, located on an i-th row (where i is an integer equal to or greater than 1 and less than or equal to m) and a j-th column (where j is an integer equal to or greater than 1 and less than or equal to n) among the sub-pixels SP of FIG. 1.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node provided to transmit the first power voltage VDD of FIG. 1. The second power voltage node VSSN may be a node provided to transmit the second power voltage VSS of FIG. 1.

An anode electrode AE of the light-emitting element LD may be connected to the first power voltage node VDDN through the sub-pixel circuit SPC. A cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light-emitting element LD in response to signals received through the aforementioned signal lines.

The sub-pixel circuit SPC may operate in response to a gate signal received through the i-th gate line GLi. The i-th gate line GLi may include one or more sub-gate lines. In embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first and second sub-gate lines SGL1 and SGL2. The sub-pixel circuit SPC may adjust current flowing from the first power voltage node VDDN to the second power voltage node VSSN through the light-emitting element LD according to the stored voltage, in response to an emission control signal received through the i-th emission control line ELi. Therefore, the light-emitting element LD may generate light with a luminance corresponding to the data signal.

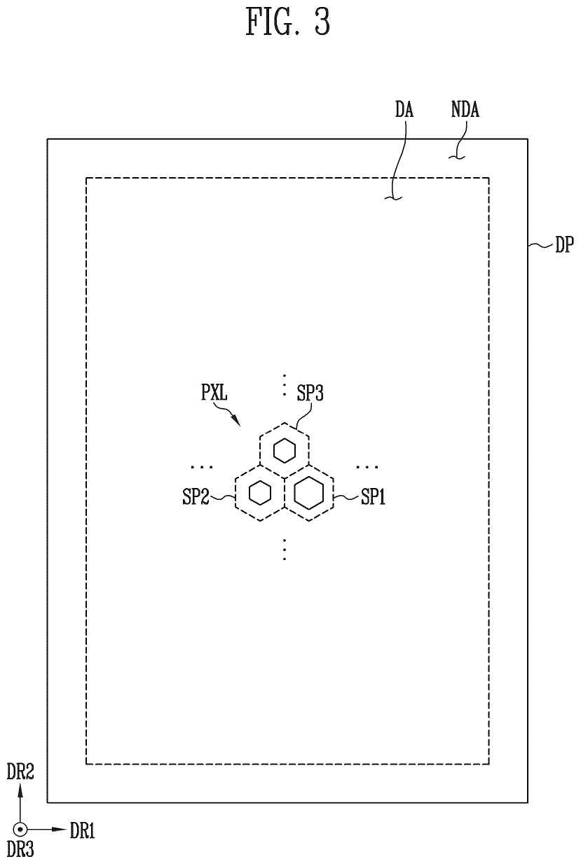

FIG. 3 is a plan view for describing the display panel 110 of FIG. 1.

Referring to FIG. 3, the display panel 110 of FIG. 1 may be implemented using a display panel DP of FIG. 3.

The display panel DP may include a display area DA and a non-display area NDA. The display panel DP may display an image through the display area DA. The non-display area NDA may be located around the display area DA (e.g., in plan view).

The display panel DP may include sub-pixels SP (refer to FIG. 1) in the display area DA. The sub-pixels SP may be arranged in a zigzag pattern in a first direction DR1. In other embodiments, the sub-pixels SP may be arranged in a matrix pattern in the first direction DR1 and a second direction DR2 crossing the first direction DR1. The arrangement of the sub-pixels SP may vary depending on embodiments.

The first direction DR1 may refer to a row direction, and the second direction DR2 may refer to a column direction.

Two or more sub-pixels SP among the sub-pixels SP may form one pixel PXL. Although FIG. 3 illustrates that the pixel PXL includes three sub-pixels SP1, SP2, and SP3, embodiments are not limited thereto. For example, the pixel PXL may include two sub-pixels SP. Hereinafter, for the sake of convenience in explanation, it is assumed that the pixel PXL includes first to third sub-pixels SP1, SP2, and SP3.

Each of the first to third sub-pixels SP1, SP2, and SP3 may generate light of one among various colors, such as red, green, blue, cyan, magenta, and yellow. Hereinafter, for clear and concise description, it is assumed that the first sub-pixel SP1 is configured to generate light in blue, the second sub-pixel SP2 is configured to generate light in green, and the third sub-pixel SP3 is configured to generate light in red.

Components for controlling the sub-pixels SP may be located in the non-display area NDA. For example, connected to the sub-pixels SP, lines such as the first to m-th gate lines GL1 to GLm and the first to n-th data lines DL1 to DLn of FIG. 1 may be located in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and positioned in the non-display area NDA. In other embodiments, the gate driver 120 may be implemented as an integrated circuit separate from the display panel DP. In embodiments, the temperature sensor 160 may be positioned in the non-display area NDA to sense the temperature of the display panel DP.

In embodiments, the display area DA may have various shapes. The display area DA may have a closed-loop shape, including linear and/or curved sides. For example, the display area DA may have shapes, such as polygons, circles, semicircles, ellipses, and the like.

In embodiments, the display panel DP may have a planar display surface. In embodiments, the display panel DP may have a display surface that is at least partially rounded. In embodiments, the display panel DP is bendable, foldable, or rollable. In the aforementioned cases, the display panel DP may include materials having flexible properties.

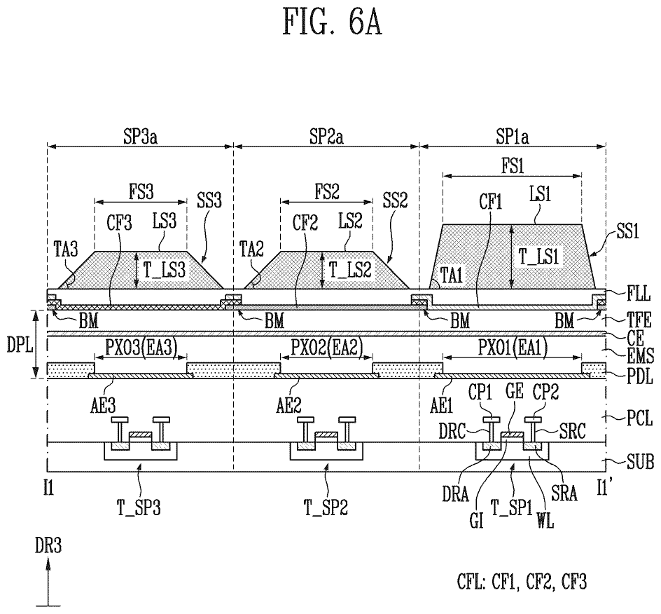

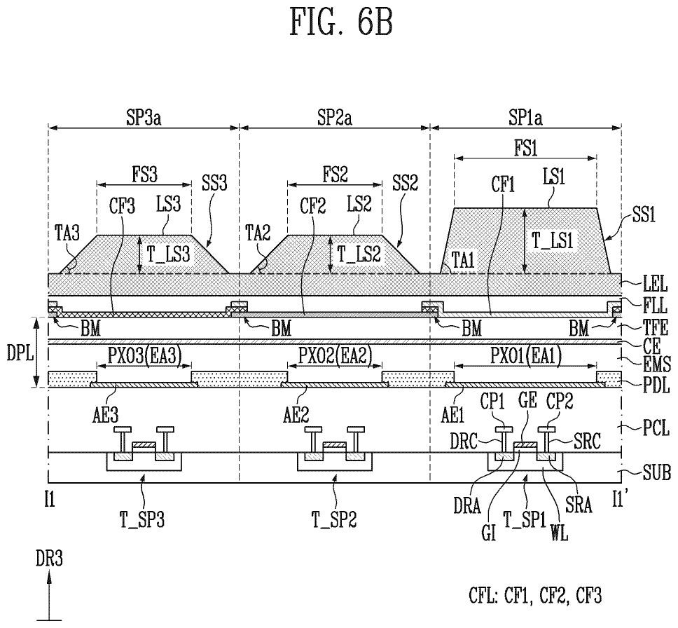

In the case where the display panel DP is used as a display screen for a head-mounted display (HMD), a virtual reality (VR) device, a mixed reality (MR) device, an augmented reality (AR) device, and the like, the display panel DP may be positioned extremely close to the eyes of a user. In this case, relatively high-density sub-pixels SP may be required. To increase the degree of integration of the sub-pixels SP, a substrate SUB (refer to FIG. 6A) that forms the display panel DP may be provided using a silicon substrate. The sub-pixels SP and/or other components of the display panel DP may be formed on the substrate SUB that is a silicon substrate. The display device 100 (refer to FIG. 1) formed of the display panel DP including the substrate SUB that is a silicon substrate may be referred to as an OLED on Silicon (OLEDoS) display device.

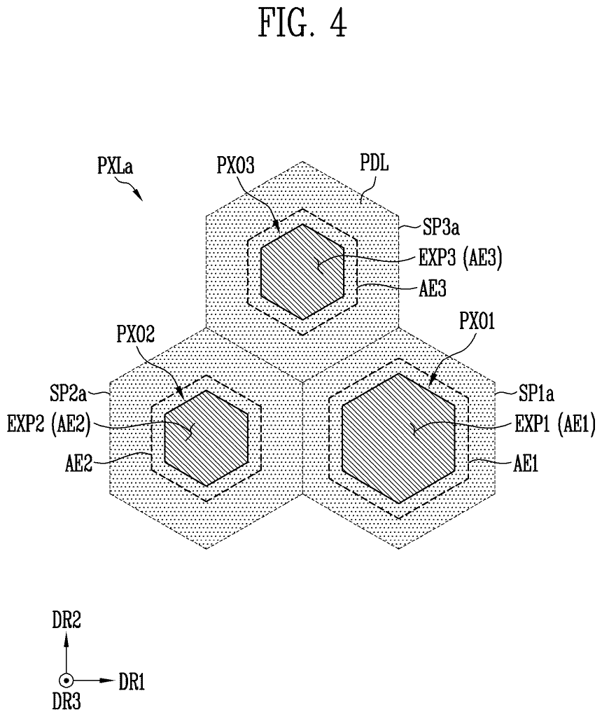

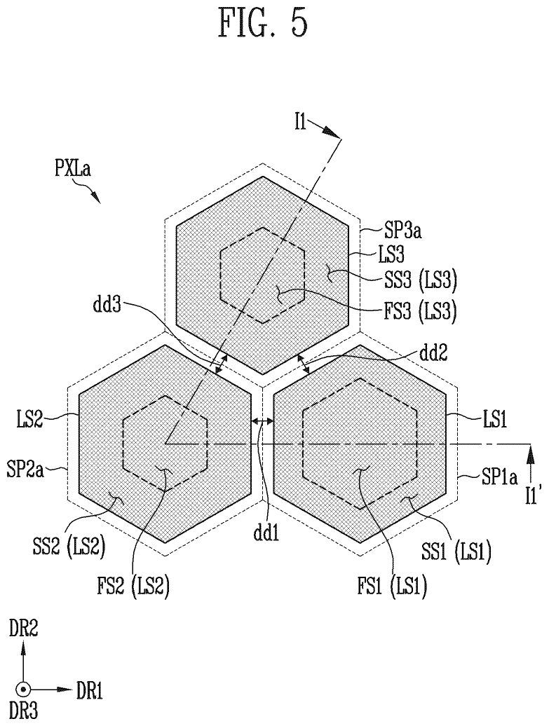

FIGS. 4 and 5 are plan views for describing one or more embodiments of any one pixel included in the display panel of FIG. 3.

Referring to FIG. 4, a pixel PXLa may include first to third sub-pixels SP1a, SP2a, and SP3a.

Areas where the first to third sub-pixels SP1a, SP2a, and SP3a are located may each have a hexagonal shape in a plan view. The first to third sub-pixels SP1a, SP2a, and SP3a may be located adjacent to each other. A plurality of pixels PXLa each including the first to third sub-pixels SP1a, SP2a, and SP3a may be provided in the display area DA, thus allowing the display area DA to be filled with the pixels PXLa without a gap.

The first sub-pixel SP1a may include a first anode electrode AE1. The first anode electrode AE1 may be provided as the anode electrode AE (refer to FIG. 2) of the first sub-pixel SP1a. The second sub-pixel SP2a may include a second anode electrode AE2. The second anode electrode AE2 may be provided as the anode electrode AE (refer to FIG. 2) of the second sub-pixel SP2a. The third sub-pixel SP3a may include a third anode electrode AE3. The third anode electrode AE3 may be provided as the anode electrode AE (refer to FIG. 2) of the third sub-pixel SP3a. The first to third anode electrodes AE1, AE2, and AE3 may be spaced apart from each other.

A pixel-defining layer PDL may be located on the first to third anode electrodes AE1, AE2, and AE3. The pixel-defining layer PDL may be located entirely in areas where the first to third sub-pixels SP1a, SP2a, and SP3a are provided.

The pixel-defining layer PDL may include a first pixel opening PXO1, a second pixel opening PXO2, and a third pixel opening PXO3.

The first pixel opening PXO1 may be formed to expose at least a portion of the first anode electrode AE1. A surface of the first anode electrode AE1 that is exposed through the first pixel opening PXO1 may be referred to as a first exposed surface EXP1. In this case, the first pixel opening PXO1 may be regarded as overlapping the first exposed surface EXP1.

The second pixel opening PXO2 may be formed to expose at least a portion of the second anode electrode AE2. A surface of the second anode electrode AE2 that is exposed through the second pixel opening PXO2 may be referred to as a second exposed surface EXP2. In this case, the second pixel opening PXO2 may be regarded as overlapping the second exposed surface EXP2.

The third pixel opening PXO3 may be formed to expose at least a portion of the third anode electrode AE3. A surface of the third anode electrode AE3 that is exposed through the third pixel opening PXO3 may be referred to as a third exposed surface EXP3. In this case, the third pixel opening PXO3 may be regarded as overlapping the third exposed surface EXP3.

The first to third exposed surfaces EXP1, EXP2, and EXP3 may be understood as areas corresponding to areas (e.g., emission areas) where light is generated (or emitted) from the light-emitting elements LD (refer to FIG. 2) of the first to third sub-pixels SP1a, SP2a, and SP3a. For example, the first exposed surface EXP1 exposed through the first pixel opening PXO1 may correspond to a first emission area EA1 (refer to FIG. 6A) of the light-emitting element LD of the first sub-pixel SP1a. The second exposed surface EXP2 exposed through the second pixel opening PXO2 may correspond to a second emission area EA2 (refer to FIG. 6A) of the light-emitting element LD of the second sub-pixel SP2a. The third exposed surface EXP3 exposed through the third pixel opening PXO3 may correspond to a third emission area EA3 (refer to FIG. 6A) of the light-emitting element LD of the third sub-pixel SP3a. Details of the first to third emission areas EA1, EA2, and EA3 will be described later with reference to FIG. 6A. In one or more embodiments, each of the first to third exposed surfaces EXP1, EXP2, and EXP3 may have an N-sided polygonal shape (where N is a natural number of 4 or more) in a plan view. For example, as illustrated in FIG. 4, each of the first to third exposed surfaces EXP1, EXP2, and EXP3 may have a hexagonal shape in a plan view.

In one or more embodiments, a planar surface area of the first exposed surface EXP1 may be greater than a planar surface area of the second exposed surface EXP2, and also may be greater than a planar surface area of the third exposed surface EXP3. In one or more embodiments, the planar surface area of the second exposed surface EXP2 may be substantially the same as the planar surface area of the third exposed surface EXP3.

In the aforementioned cases, the planar shapes and the planar surface areas of the first to third emission areas EA1, EA2, and EA3 may be substantially the same as the planar shapes and the planar surface areas of the first to third exposed surfaces EXP1, EXP2, and EXP3, respectively.

Referring to FIG. 5, there are illustrated first to third lens structures LS1, LS2, and LS3 located on the first to third anode electrodes AE1, AE2, and AE3, respectively.

The first lens structure LS1 may overlap the first anode electrode AE1. The second lens structure LS2 may overlap the second anode electrode AE2. The third lens structure LS3 may overlap the third anode electrode AE3. In this case, the first to third lens structures LS1, LS2, and LS3 may respectively overlap the first to third emission areas EA1, EA2, and EA3.

The first to third lens structures LS1, LS2, and LS3 may function to enhance the output efficiency of light generated (or emitted) from the first to third emission areas EA1, EA2, and EA3, respectively. For example, light emitted from the first emission area EA1 defined as the area corresponding to the first exposed surface EXP1 may pass through the first lens structure LS1. The light that passes through the first lens structure LS1 may be visible to the user of the display device 100 in a first light output area. The first light output area may have a relatively large planar surface area compared to the first emission area EA1. The second and third lens structures LS2 and LS3 may also perform substantially the same (or similar) function as the first lens structure LS1.

In one or more embodiments, each of the first to third lens structures LS1, LS2, and LS3 may have an M-sided polygonal shape (where M is a natural number of 4 or more) in a plan view. In this case, M is the same natural number as N. In other words, the planar shapes of the first to third lens structures LS1, LS2, and LS3 may be substantially the same (e.g., hexagonal) as the planar shapes of the first to third exposed surfaces EXP1, EXP2, and EXP3, respectively.

In one or more embodiments, upper surfaces of the first to third lens structures LS1, LS2, and LS3 may be provided as flat surfaces. The upper surface of the first lens structure LS1 may be a first flat surface FS1, and a side surface of the first lens structure LS1 that is adjacent to the upper surface may be a first side surface SS1. The upper surface of the second lens structure LS2 may be a second flat surface FS2, and a side surface of the second lens structure LS2 that is adjacent to the upper surface may be a second side surface SS2. The upper surface of the third lens structure LS3 may be a third flat surface FS3, and a side surface of the third lens structure LS3 that is adjacent to the upper surface may be a third side surface SS3. In this case, the first to third flat surfaces FS1, FS2, and FS3 may completely overlap the first to third exposed surfaces EXP1, EXP2, and EXP3, respectively.

In other words, the first flat surface FS1 may completely overlap the first exposed surface EXP1 in a plan view, and may have substantially the same planar shape and planar surface area. The second flat surface FS2 may completely overlap the second exposed surface EXP2 in a plan view, and may have substantially the same planar shape and planar surface area. The third flat surface FS3 may completely overlap the third exposed surface EXP3 in a plan view, and may have substantially the same planar shape and planar surface area. In this case, the planar surface area of the first flat surface FS1 may be greater than the planar surface area of the second flat surface FS2, and also may be greater than the planar surface area of the third flat surface FS3. Furthermore, the planar surface area of the second flat surface FS2 may be substantially the same as the planar surface area of the third flat surface FS3.

In one or more embodiments, the first to third lens structures LS1, LS2, and LS3 may have the same planar surface areas. Furthermore, the first to third lens structures LS1, LS2, and LS3 may have the same planar shapes.

The first to third lens structures LS1, LS2, and LS3 may be spaced apart from each other. In one or more embodiments, a first shortest distance dd1 between the first lens structure LS1 and the second lens structure LS2, a second shortest distance dd2 between the first lens structure LS1 and the third lens structure LS3, and a third shortest distance dd3 between the second lens structure LS2 and the third lens structure LS3 may be substantially the same as each other. Accordingly, spatial efficiency for forming the first to third lens structures LS1, LS2, and LS3 in a limited planar surface area may be further enhanced.

FIG. 6A is a sectional view taken along the line I1-I1′ of FIG. 5.

Referring to FIGS. 4, 5, and 6A, the pixel PXLa (or the display panel DP including the pixel PXLa) may include the substrate SUB, a pixel circuit layer PCL, a display element layer DPL, a color filter layer CFL, a planarization layer FLL, and the first to third lens structures LS1, LS2, and LS3.

The substrate SUB may be a silicon wafer substrate formed through a semiconductor process. For example, the substrate SUB may include silicon, germanium, and/or silicon-germanium.

The pixel circuit layer PCL may be located on the substrate SUB (as used herein, “located on” may mean “above”). The substrate SUB and the pixel circuit layer PCL may include respective circuit elements of the first to third sub-pixels SP1a, SP2a, and SP3a. For example, the substrate SUB and the pixel circuit layer PCL may include a transistor T_SP1 of the first sub-pixel SP1a, a transistor T_SP2 of the second sub-pixel SP2a, and a transistor T_SP3 of the third sub-pixel SP3a.

The transistor T_SP1 of the first sub-pixel SP1a may be any one of the transistors included in the sub-pixel circuit SPC (refer to FIG. 2) of the first sub-pixel SP1a. The transistor T_SP2 of the second sub-pixel SP2a may be any one of the transistors included in the sub-pixel circuit SPC (refer to FIG. 2) of the second sub-pixel SP2a. The transistor T_SP3 of the third sub-pixel SP3a may be any one of the transistors included in the sub-pixel circuit SPC (refer to FIG. 2) of the third sub-pixel SP3a. In FIG. 6A, one of the transistors that form each sub-pixel is illustrated for the sake of clear and concise explanation, and the remaining circuit circuits are omitted.

The transistor T_SP1 of the first sub-pixel SP1a may include a source area SRA, a drain area DRA, and a gate electrode GE.

The source area SRA and the drain area DRA may be located in the substrate SUB. Formed through an ion injection process, a well WL may be located in the substrate SUB. The source area SRA and the drain area DRA may be spaced apart from each other in the well WL. An area between the source area SRA and the drain area DRA in the well WL may be defined as a channel area. The gate electrode GE may overlap the channel area between the source area SRA and the drain area DRA, and may be located in the pixel circuit layer PCL. The gate electrode GE may be spaced apart from the well WL or the channel area by an insulating material, such as a gate-insulating layer GI. The gate electrode GE may include conductive material.

A plurality of layers included in the pixel circuit layer PCL may include insulating layers and conductive patterns (or semiconductor patterns) located between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 are connected to other circuit elements and/or lines, the transistor T_SP1 of the first sub-pixel SP1a may be provided as one of the transistors of the first sub-pixel SP1a.

Each of the transistor T_SP2 of the second sub-pixel SP2a and the transistor T_SP3 of the third sub-pixel SP3a may be configured to be substantially the same as (or similar to) the transistor T_SP1 of the first sub-pixel SP1a.

As such, the substrate SUB and the pixel circuit layer PCL may include circuit elements that form the respective sub-pixel circuits SPC of the first to third sub-pixels SP1a, SP2a, and SP3a.

The display element layer DPL may be located on the pixel circuit layer PCL. The display element layer DPL may include first to third anode electrodes AE1, AE2, and AE3, a pixel-defining layer PDL, an emission structure EMS, a cathode electrode CE, and an encapsulation layer TFE.

The first to third anode electrodes AE1, AE2, and AE3 may be located on the pixel circuit layer PCL to be spaced apart from each other. The first to third anode electrodes AE1, AE2, and AE3 may be electrically connected to the circuit elements of the pixel circuit layer PCL and the substrate SUB. For example, the first anode electrode AE1 may be electrically connected to the circuit elements that define the sub-pixel circuit SPC (refer to FIG. 2) of the first sub-pixel SP1a. The second anode electrode AE2 may be electrically connected to the circuit elements that define the sub-pixel circuit SPC of the second sub-pixel SP2a. The third anode electrode AE3 may be electrically connected to the circuit elements that define the sub-pixel circuit SPC of the third sub-pixel SP3a.

The pixel-defining layer PDL may be located on the pixel circuit layer PCL and the first to third anode electrodes AE1, AE2, and AE3. The pixel-defining layer PDL may include first to third pixel openings PXO1, PXO2, and PXO3 that respectively expose the first to third anode electrodes AE1, AE2, and AE3. The pixel-defining layer PDL may have a structure in which a plurality of inorganic insulating layers are sequentially stacked in a third direction DR3. The third direction DR3 may be a direction perpendicular to the first and second directions DR1 and DR2. Each of the inorganic insulating layers may include at least one of silicon oxide and silicon nitride.

In one or more embodiments, the pixel-defining layer PDL may include various components causing formation of a discontinuous portion of the emission structure EMS in a boundary area between adjacent sub-pixels. For example, the pixel-defining layer PDL may include a groove recessed in a direction opposite to the third direction DR3 in the boundary area. As another example, the pixel-defining layer PDL may include a separator protruding in the third direction DR3 in the boundary area. Accordingly, the emission structure EMS may be severed or bent in the boundary area.

The emission structure EMS may be located on the first to third exposed surfaces EXP1, EXP2, and EXP3 (e.g., see FIG. 4) of the first to third anode electrodes AE1, AE2, and AE3 that are exposed through the first to third pixel openings PXO1, PXO2, and PXO3 of the pixel-defining layer PDL. The emission structure EMS may be charged into the first to third pixel openings PXO1, PXO2, and PXO3 of the pixel-defining layer PDL, and may be located entirely across the areas where the first to third sub-pixels SP1a, SP2a, and SP3a are provided. In this case, as described above, the emission structure EMS may be partially severed or bent in the boundary area. Consequently, during the operation of the display panel DP, current leaking from each of the first to third sub-pixels SP1a, SP2a, and SP3a to an adjacent sub-pixel through the layers included in the emission structure EMS may be reduced. As a result, operational reliability of the first to third sub-pixels SP1a, SP2a, and SP3a may be enhanced.

The cathode electrode CE may be located on the emission structure EMS. The cathode electrode CE may be provided in common to the first to third sub-pixels SP1a, SP2a, and SP3a. The cathode electrode CE may function as a half mirror, partially transmitting and partially reflecting light emitted from the emission structure EMS. In this case, a resonant structure in which light emitted from the emission structure EMS resonates between the cathode electrode CE and the first to third anode electrodes AE1, AE2, and AE3 facing the cathode electrode CE may be provided. The resonant structure may be designed to effectively and efficiently amplify light in a wavelength range of a corresponding color emitted from each of the first to third sub-pixels SP1a, SP2a, and SP3a.

The emission structure EMS interposed between the cathode electrode CE and each of the first to third anode electrodes AE1, AE2, and AE3 may be provided as the light-emitting element LD (refer to FIG. 2) of each of the first to third sub-pixels SP1a, SP2a, and SP3a.

For example, the emission structure EMS that is interposed between the first exposed surface EXP1 of the first anode electrode AE1 exposed through the first pixel opening PXO1 and the cathode electrode CE overlapping the first exposed surface EXP1 may function as the light-emitting element LD of the first sub-pixel SP1a. In this case, the first emission area EA1 of the light-emitting element LD of the first sub-pixel SP1a may be understood as an area corresponding to the first exposed surface EXP1.

The emission structure EMS that is interposed between the second exposed surface EXP2 of the second anode electrode AE2 exposed through the second pixel opening PXO2 and the cathode electrode CE overlapping the second exposed surface EXP2 may function as the light-emitting element LD of the second sub-pixel SP2a. In this case, the second emission area EA2 of the light-emitting element LD of the second sub-pixel SP2a may be understood as an area corresponding to the second exposed surface EXP2.

The emission structure EMS that is interposed between the third exposed surface EXP3 of the third anode electrode AE3 exposed through the third pixel opening PXO3 and the cathode electrode CE overlapping the third exposed surface EXP3 may function as the light-emitting element LD of the third sub-pixel SP3a. In this case, the third emission area EA3 of the light-emitting element LD of the third sub-pixel SP3a may be understood as an area corresponding to the third exposed surface EXP3.

The first to third emission areas EA1, EA2, and EA3 may correspond to areas through which light generated from the emission structure EMS is substantially emitted.

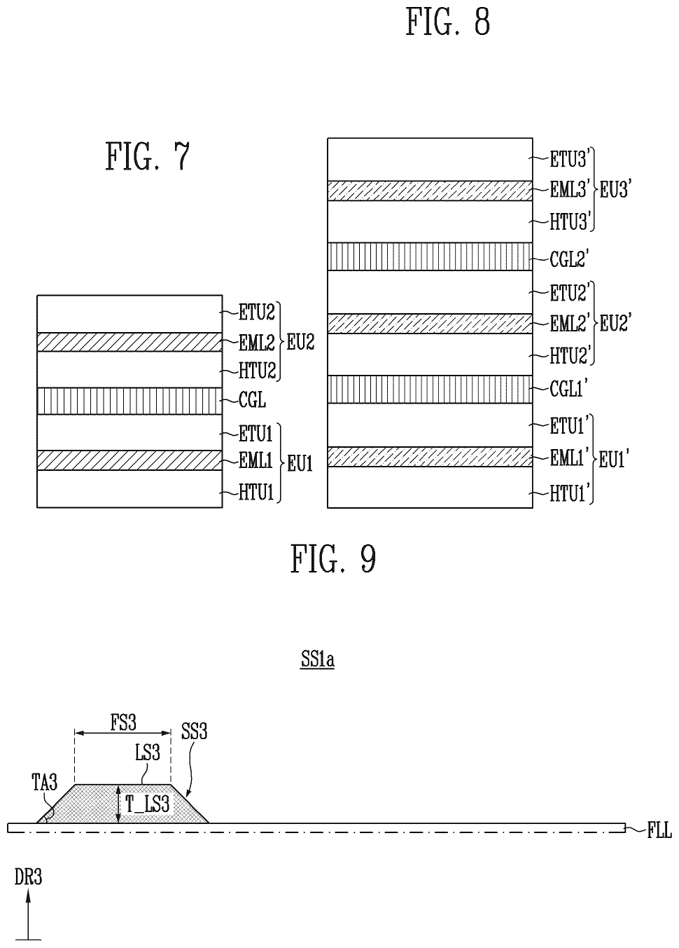

The emission structure EMS may include a tandem structure. Details of the emission structure EMS will be described later with reference to FIGS. 7 and 8.

The encapsulation layer TFE may be located on the cathode electrode CE. The encapsulation layer TFE may function to reduce or prevent oxygen, water, and/or the like penetrating into components located under the encapsulation layer TFE.

The color filter layer CFL may be located on the encapsulation layer TFE. The color filter layer CFL may be configured to filter light emitted from the emission structure EMS to selectively output light in a wavelength range (or color) corresponding to each sub-pixel. The color filter layer CFL may include first to third color filters CF1, CF2, and CF3 that respectively correspond to the first to third sub-pixels SP1a, SP2a, and SP3a. Each of the first to third color filters CF1, CF2, and CF3 allows light in a corresponding wavelength range to pass therethrough.

For example, the color filter layer CFL may include the first color filter CF1 corresponding to the first sub-pixel SP1a, the second color filter CF2 corresponding to the second sub-pixel SP2a, and the third color filter CF3 corresponding to the third sub-pixel SP3a.

The first color filter CF1 may be a blue color filter allowing blue light to selectively pass therethrough. The first color filter CF1 may overlap the first exposed surface EXP1. Accordingly, blue light among the light emitted from the first emission area EA1 may pass through the first color filter CF1, and may be directed to the first lens structure LS1. Consequently, the first sub-pixel SP1a may be provided as a blue sub-pixel.

The second color filter CF2 may be a green color filter allowing green light to selectively pass therethrough. The second color filter CF2 may overlap the second exposed surface EXP2. Accordingly, green light among the light emitted from the second emission area EA2 may pass through the second color filter CF2, and may be directed to the second lens structure LS2. Consequently, the second sub-pixel SP2a may be provided as a green sub-pixel.

The third color filter CF3 may be a red color filter allowing red light to selectively pass therethrough. The third color filter CF3 may overlap the third exposed surface EXP3. Accordingly, red light among the light emitted from the third emission area EA3 may pass through the third color filter CF3, and may be directed to the third lens structure LS3. Consequently, the third sub-pixel SP3a may be provided as a red sub-pixel.

In one or more embodiments, the first to third color filters CF1, CF2, and CF3 may be stacked in the boundary area between adjacent sub-pixels, thereby defining a light-blocking component BM. The light-blocking component BM may function to reduce or prevent light mixing between adjacent sub-pixels.

The planarization layer FLL may be located on the color filter layer CFL. The planarization layer FLL may cover the entirety of the color filter layer CFL. The planarization layer FLL may substantially provide a flat upper surface.

The first to third lens structures LS1, LS2, and LS3 may be located on the planarization layer FLL. The first to third lens structures LS1, LS2, and LS3 may function to enhance the output efficiency of light emitted from the first to third emission areas EA1, EA2, and EA3.

In one or more embodiments, the first to third lens structures LS1, LS2, and LS3 may include organic insulating material having a refractive index suitable for improving light output efficiency. For example, the first to third lens structures LS1, LS2, and LS3 may include organic insulating material having a relatively high refractive index.

In one or more embodiments, in a cross-sectional view, each of the first to third lens structures LS1, LS2, and LS3 may have a trapezoidal shape in which a length of a top side is less than a length of a bottom side. In this case, the upper surfaces of the first to third lens structures LS1, LS2, and LS3 may be respectively the first to third flat surfaces FS1, FS2, and FS3. The side surfaces of the first to third lens structures LS1, LS2, and LS3 may be respectively the first to third side surfaces SS1, SS2, and SS3.

In this case, the first flat surface FS1 of the first lens structure LS1 may substantially completely overlap the first exposed surface EXP1 of the first anode electrode AE1. In other words, the first flat surface FS1 of the first lens structure LS1 may have a relatively large planar surface area compared to the second and third flat surfaces FS2 and FS3, so that the first flat surface FS1 can completely overlap the first emission area EA1.

Among the light emitted from the first emission area EA1, light traveling in the third direction DR3 or in a direction substantially parallel to the third direction DR3 may pass through the first flat surface FS1 of the first lens structure LS1, and may be visible to the user of the display device 100. In this way, as the first flat surface FS1 is formed to substantially completely overlap the first emission area EA1, light traveling in the third direction DR3 or in the direction substantially parallel to the third direction DR3, among the light emitted from the first emission area EA1, may pass through the first flat surface FS1, and may be provided to the user of the display device 100.

Among the light emitted from the first emission area EA1, light traveling in a direction crossing the third direction DR3 may pass through the first side surface SS1 of the first lens structure LS1. As the first side surface SS1 is inclined at a first taper angle TA1 relative to the upper surface of the planarization layer FLL, light traveling in a direction crossing the third direction DR3 may be refracted in such a way that a path of the light is changed to the third direction DR3 or the direction substantially parallel to the third direction DR3 when the light passes through the first side surface SS1. As such, light traveling in a direction crossing the third direction DR3 among the light emitted from the first emission area EA1 may be provided to the user of the display device 100.

In other words, the first lens structure LS1 may function to control the path of light emitted from the first emission area EA1 in various directions, and to direct the light to the user of the display device 100.

The second and third lens structures LS2 and LS3 may also function similarly to the first lens structure LS1. In other words, the second and third lens structures LS2 and LS3 may function to control the paths of light emitted from the second and third emission areas EA2 and EA3 in various directions, and may provide the light to the user of the display device 100.

In one or more embodiments, thicknesses of the first to third lenses structures LS1, LS2, and LS3 may be generally proportional to the planar surface areas (refer to FIG. 4) of the first to third exposed surfaces EXP1, EXP2, and EXP3 of the first to third anode electrodes AE1, AE2, and AE3, respectively.

For example, as described with reference to FIG. 4, the planar surface area of the first exposed surface EXP1 may be greater than the planar surface area of each of the second and third exposed surfaces EXP2 and EXP3. The planar surface area of the second exposed surface EXP2 may be substantially the same as the planar surface area of the third exposed surface EXP3. In this case, a first thickness T_LS1 of the first lens structure LS1 may be greater than a second thickness T_LS2 of the second lens structure LS2, and may be greater than a third thickness T_LS3 of the third lens structure LS3. Furthermore, the second thickness T_LS2 of the second lens structure LS2 may be substantially the same as the third thickness T_LS3 of the third lens structure LS3.

As the first to third lens structures LS1, LS2, and LS3 respectively have the first to third thicknesses T_LS1, T_LS2, and T_LS3, the first taper angle TA1 between the first side surface SS1 and the upper surface of the planarization layer FLL may be greater than a second taper angle TA2 between the second side surface SS2 and the upper surface of the planarization layer FLL, and also may be greater than a third taper angle TA3 between the third side surface SS3 and the upper surface of the planarization layer FLL. The second taper angle TA2 and the third taper angle TA3 may be substantially the same as each other.

As described above, the planar surface area of the first flat surface FS1 may be formed to be relatively large to correspond to the first exposed surface EXP1 having a relatively large planar surface area. In this case, if it is assumed that the first thickness T_LS1 is substantially the same as each of the second and third thicknesses T_LS2 and T_LS3, a sufficient surface area of the first side surface SS1 may not be secured. In the case where a sufficient surface area of the first side surface SS1 is not secured, there may be a problem that light traveling in a direction crossing the third direction DR3, among the light emitted from the first emission area EA1, is not sufficiently provided to the user of the display device 100. In the present disclosure, the first thickness T_LS1 may be greater than each of the second and third thicknesses T_LS2 and T_LS3. Therefore, a sufficient surface area of the first side surface SS1 of the first lens structure LS1 may be secured. Accordingly, light traveling in a direction crossing the third direction DR3 among the light emitted from the first emission area EA1 may be sufficiently provided to the user of the display device 100.

FIG. 6B is a sectional view taken along the line I1-I1′ of FIG. 5.

Hereinafter, the following description with reference to FIG. 6B will focus on differences from FIG. 6A, and any omitted content will be covered by the aforementioned descriptions.

Referring to FIGS. 4, 5, and 6B, a light extraction layer LEL may be located on the planarization layer FLL. The light extraction layer LEL may include organic insulating material having a relatively high refractive index. The first to third lens structures LS1, LS2, and LS3 may be located on the light extraction layer LEL.

In this case, the first to third lens structures LS1, LS2, and LS3 may be formed integrally with the light extraction layer LEL. In other words, the first to third lens structures LS1, LS2, and LS3 may be structures protruding from the light extraction layer LEL in the third direction DR3.

Hereinafter, various embodiments of the emission structure EMS having a tandem structure will be described with reference to FIGS. 7 and 8. However, the emission structure EMS is not limited to the embodiments of FIGS. 7 and 8 to be described below. The emission structure EMS may have any one of various known tandem structures without limitation.

FIG. 7 is a diagram for describing one or more embodiments of the emission structure EMS of FIG. 6A.

Referring to FIG. 7, the emission structure EMS in accordance with one or more embodiments may have a tandem structure in which first and second emission components EU1 and EU2 are stacked.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be located between the first electron transport component ETU1 and the first hole transport component HTU1. The second emission component EU2 may include a second emission layer EML2, a second electron transport component ETU2, and a second hole transport component HTU2. The second emission layer EML2 may be located between the second electron transport component ETU2 and the second hole transport component HTU2.

Each of the first and second hole transport components HTU1 and HTU2 may include at least one of a hole injection layer and a hole transport layer, and may further include a hole buffer layer, an electron-blocking layer, and the like, as needed. The first and second hole transport components HTU1 and HTU2 may have the same configuration or have different configurations.

Each of the first and second electron transport components ETU1 and ETU2 may include at least one of an electron injection layer and an electron transport layer, and may further include an electron buffer layer, a hole-blocking layer, and the like, as needed. The first and second electron transport components ETU1 and ETU2 may have the same configuration or have different configurations.

A connection layer, which can be provided in the form of a charge generation layer CGL, may be located between the first emission component EU1 and the second emission component EU2 to connect the first and second emission components EU1 and EU2 to each other. In embodiments, the charge generation layer CGL may have a stacked structure including a P-type dopant layer and an N-type dopant layer. For example, the P-type dopant layer may include a P-type dopant, such as HAT-CN, TCNQ, or NDP-9, and the N-type dopant layer may include alkali metal, alkaline earth metal, lanthanide metal, or a combination thereof. However, the embodiments are not limited to the aforementioned example.

In embodiments, the first emission layer EML1 and the second emission layer EML2 may generate light in different colors. The light emitted from the first emission layer EML1 and the second emission layer EML2 may be mixed to be visible as white light. For instance, the first emission layer EML1 may generate light in blue, and the second emission layer EML2 may generate light in yellow. In embodiments, the second emission layer EML2 may include a stacked structure including a first sub-emission layer configured to generate light in red, and a second sub-emission layer configured to generate light in green. Light in red and light in green may be mixed to provide light in yellow. In this case, an intermediate layer configured to perform functions of transporting holes and/or blocking the transport of electrons may be further located between the first and second sub-emission layers.

In embodiments, the first emission layer EML1 and the second emission layer EML2 may generate light in the same color.

The emission structure EMS may be formed through a scheme, such as vacuum deposition, inkjet printing, or the like, but embodiments are not limited thereto.

FIG. 8 is a diagram for describing one or more other embodiments of the emission structure EMS of FIG. 6A.

Referring to FIG. 8, the emission structure EMS may have a tandem structure in which first to third emission components EU1′, EU2′, and EU3′ are stacked.

Each of the first to third emission components EU1′, EU2′, and EU3′ may include an emission layer configured to generate light in response to current applied thereto. The first emission component EU1′ may include a first emission layer EML1′, a first electron transport component ETU1′, and a first hole transport component HTU1′. The first emission layer EML1′ may be located between the first electron transport component ETU1′ and the first hole transport component HTU1′. The second emission component EU2′ may include a second emission layer EML2′, a second electron transport component ETU2′, and a second hole transport component HTU2′. The second emission layer EML2′ may be located between the second electron transport component ETU2′ and the second hole transport component HTU2′. The third emission component EU3′ may include a third emission layer EML3′, a third electron transport component ETU3′, and a third hole transport component HTU3′.

The third emission layer EML3′ may be located between the third electron transport component ETU3′ and the third hole transport component HTU3′.

Each of the first to third hole transport components HTU1′, HTU2′, and HTU3′ may include at least one of a hole injection layer and a hole transport layer, and may further include a hole buffer layer, an electron-blocking layer, and the like, as needed. The first to third hole transport components HTU1′, HTU2′, and HTU3′ may have the same configuration or have different configurations.

Each of the first to third electron transport components ETU1′, ETU2′, and ETU3′ may include at least one of an electron injection layer and an electron transport layer, and may further include an electron buffer layer, a hole-blocking layer, and the like, as needed. The first to third electron transport components ETU1′, ETU2′, and ETU3′ may have the same configuration or have different configurations.

A first charge generation layer CGL1′ may be located between the first emission component EU1′ and the second emission component EU2′. A second intermediate layer CGL2′ may be located between the second emission component EU2′ and the third emission component EU3′.

In embodiments, the first to third emission layers EML1′, EML2′, and EML3′ may generate light in different colors. Light emitted from the first to third emission layers EML1′, EML2′, and EML3′ may be mixed to be visible as white light. For example, the first emission layer EML1′ may generate light in blue, the second emission layer EML2′ may generate light in green, and the third emission layer EML3′ may generate light in red.

In embodiments, two or more emission layers among the first to third emission layers EML1′, EML2′, and EML3′ may generate light in the same color.

Hereinafter, a method of fabricating the pixel PXLa (or the display panel DP including the pixel PXLa) described with reference to FIGS. 4, 5, and 6A in accordance with various embodiments will be described. Here, descriptions of content that overlap the aforementioned details may be omitted.

FIGS. 9 to 11 are sectional views for describing first one or more embodiments of the method of fabricating the display device including the pixel of FIG. 6A.

Referring to FIG. 9, the third lens structure LS3 may be formed on the planarization layer FLL (at operation SS1a).

The third lens structure LS3 may be formed, for example, by a single exposure and development process using photoresist material. However, the method of forming the third lens structure LS3 is not limited to the aforementioned example, and various known methods may be used without limitation.

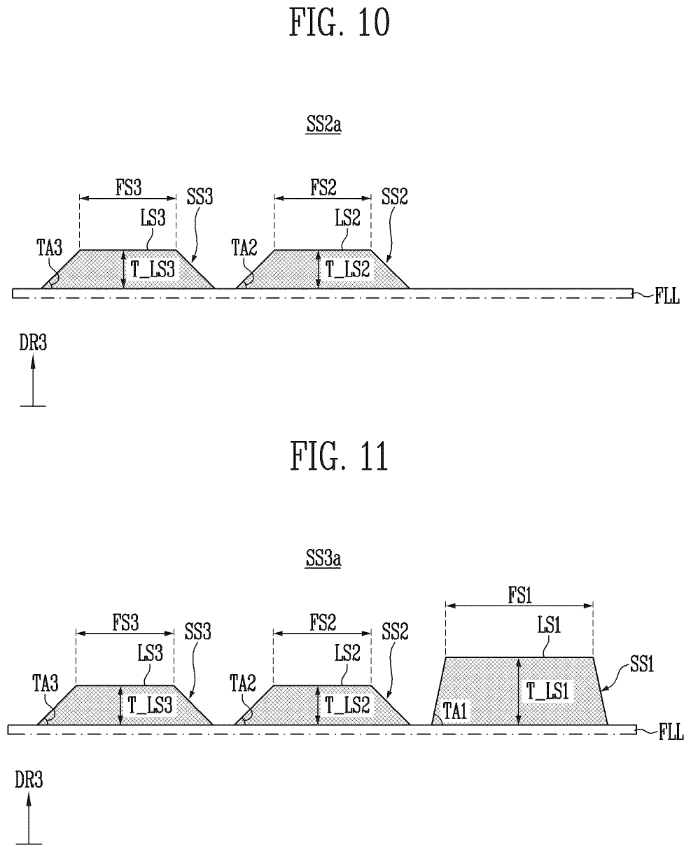

Referring to FIG. 10, the second lens structure LS2 may be formed on the planarization layer FLL (at operation SS2a).

The second lens structure LS2 may be formed, for example, by a single exposure and development process using photoresist material. However, the method of forming the second lens structure LS2 is not limited to the aforementioned example, and various known methods may be used without limitation.

Referring to FIG. 11, the first lens structure LS1 may be formed on the planarization layer FLL (at operation SS3a).

The first lens structure LS1 may be formed, for example, by a single exposure and development process using photoresist material. However, the method of forming the first lens structure LS1 is not limited to the aforementioned example, and various known methods may be used without limitation.

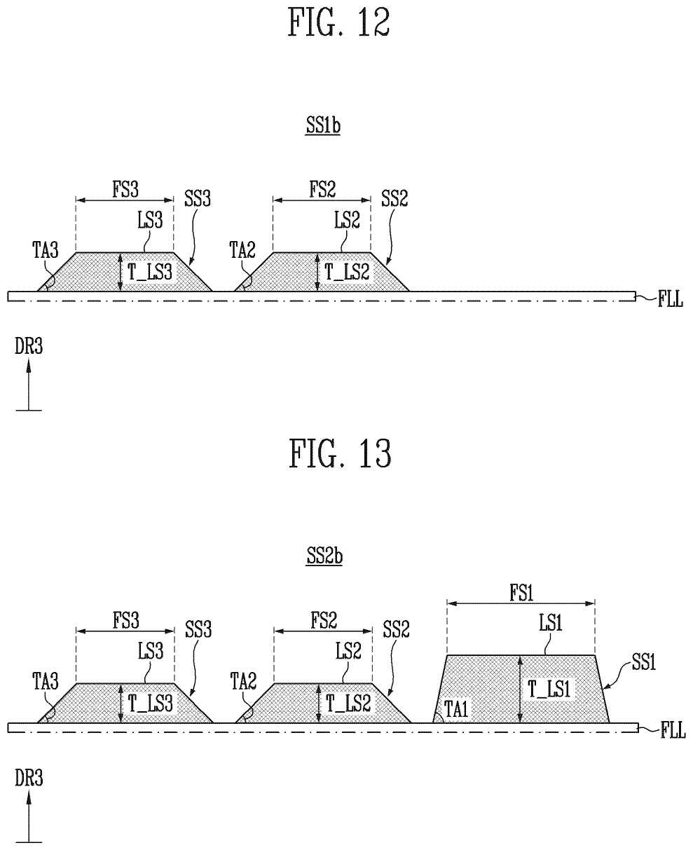

FIGS. 12 and 13 are sectional views for describing second one or more embodiments of the method of fabricating the display device including the pixel of FIG. 6A.

Referring to FIG. 12, the second and third lens structures LS2 and LS3 may be formed on the planarization layer FLL (at operation SS1b).

The second and third lens structures LS2 and LS3 may be concurrently or substantially simultaneously formed, for example, by a single exposure and development process using photoresist material. However, the method of forming the second and third lens structures LS2 and LS3 is not limited to the aforementioned example, and various known methods may be used without limitation.

Referring to FIG. 13, the first lens structure LS1 may be formed on the planarization layer FLL (at operation SS2b).

The first lens structure LS1 may be formed, for example, by a single exposure and development process using photoresist material. However, the method of forming the first lens structure LS1 is not limited to the aforementioned example, and various known methods may be used without limitation.

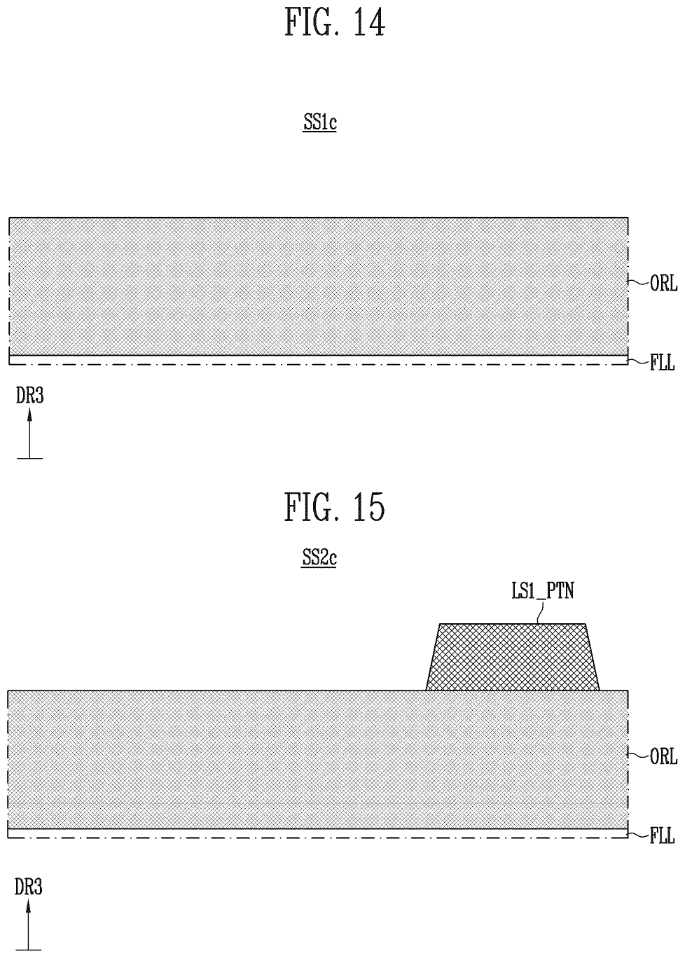

FIGS. 14 to 18 are sectional views for describing third one or more embodiments of the method of fabricating the display device including the pixel of FIG. 6A.

Referring to FIG. 14, an organic layer ORL may be formed on the planarization layer FLL (at operation SS1c). The organic layer ORL may include substantially the same material as the first to third lens structures LS1, LS2, and LS3 described with reference to FIG. 6A.

Referring to FIG. 15, a first lens pattern LS1_PTN may be formed on the organic layer ORL (at operation SS2c).

The first lens pattern LS1_PTN may be formed in substantially the same shape and at substantially the same position as the first lens structure LS1 described with reference to FIG. 6A. The first lens pattern LS1_PTN may be formed, for example, by a single exposure and development process using photoresist material.

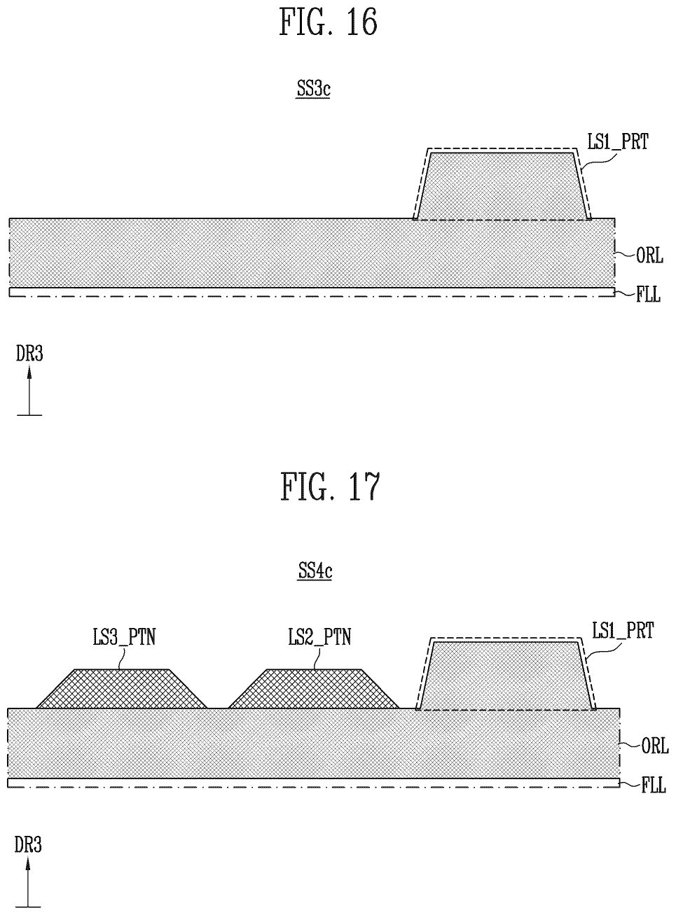

Referring to FIG. 16, after operation SS2c, an etch-back process for the entire surface may be performed (at operation SS3c).

The organic layer ORL and the first lens pattern LS1_PTN may be etched overall, thus forming a first lens protrusion LS1_PRT protruding from an upper surface of the organic layer ORL. The first lens protrusion LS1_PRT may be formed in substantially the same shape and at substantially the same position as the first lens structure LS1 described with reference to FIG. 6A.

Referring to FIG. 17, the second and third lens patterns LS2_PTN and LS3_PTN may be formed on the organic layer ORL (at operation SS4c).

The second lens pattern LS2_PTN may be formed in substantially the same shape and at substantially the same position as the second lens structure LS2 described with reference to FIG. 6A.

The third lens pattern LS3_PTN may be formed in substantially the same shape and at substantially the same position as the third lens structure LS3 described with reference to FIG. 6A.

The second and third lens patterns LS2_PTN and LS3_PTN may be concurrently or substantially simultaneously formed, for example, by a single exposure and development process using photoresist material.

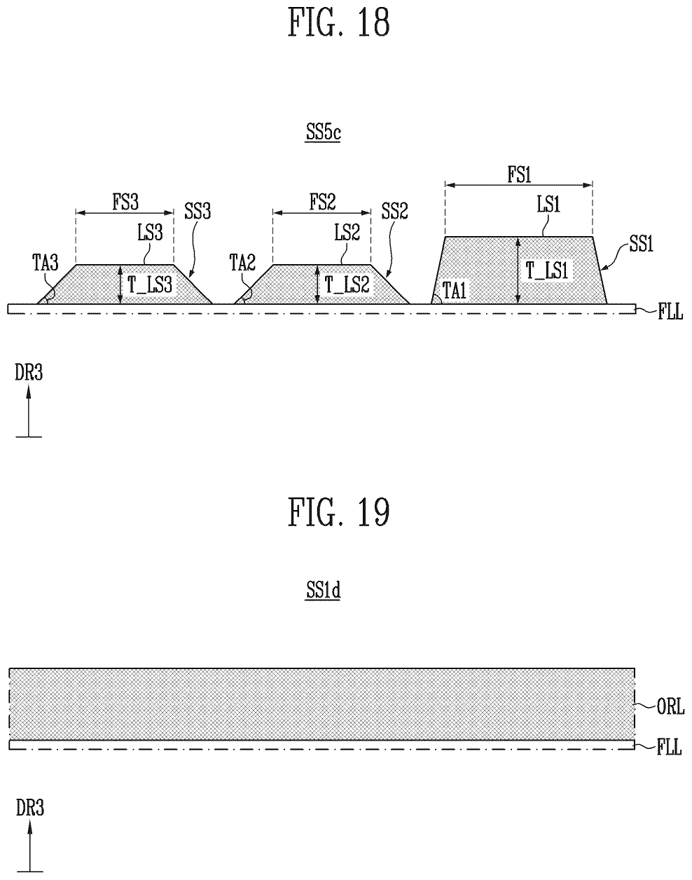

Referring to FIG. 18, after operation SS4c, an etch-back process for the entire surface may be performed (at operation SS5c). Accordingly, the first to third lens structures LS1, LS2, and LS3 may be provided.

FIGS. 19 to 22 are sectional views for describing fourth one or more embodiments of the method of fabricating the display device including the pixel of FIG. 6A.

Referring to FIG. 19, an organic layer ORL may be formed on the planarization layer FLL (at operation SS1d). The organic layer ORL may include substantially the same material as the first to third lens structures LS1, LS2, and LS3 described with reference to FIG. 6A.

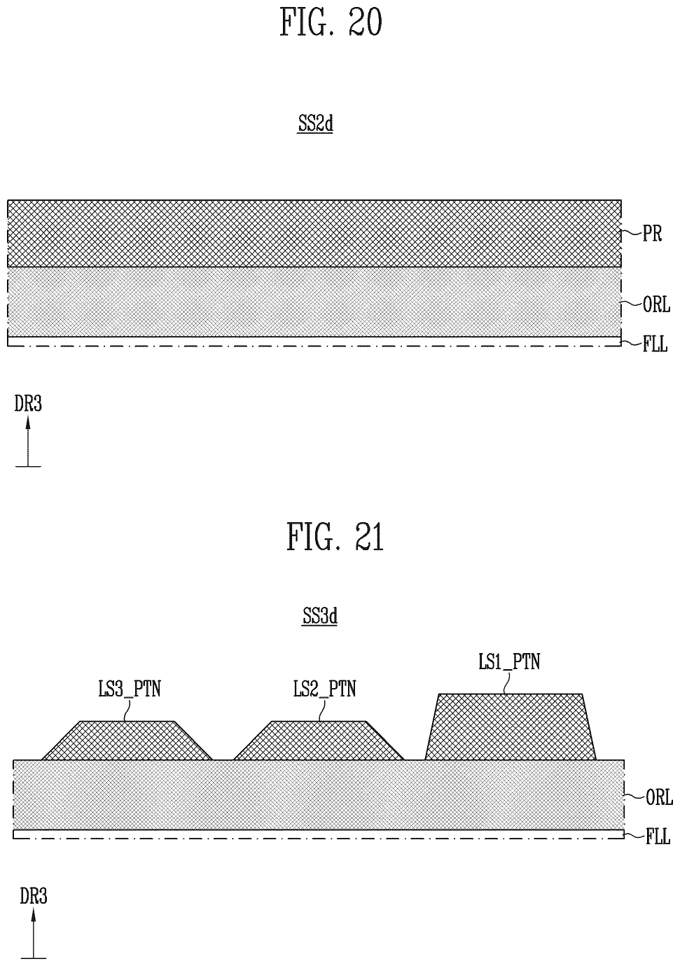

Referring to FIG. 20, a photoresist material layer PR may be formed on the organic layer ORL.

Referring to FIG. 21, the photoresist material layer PR may be differentially exposed and developed to concurrently or substantially simultaneously form first to third lens patterns LS1_PTN, LS2_PTN, and LS3_PTN (at operation SS3d).

In this case, the differential exposure of the photoresist material layer PR may be performed, for example, using a halftone mask or the like, but the present disclosure is not limited thereto.

The first to third lens patterns LS1_PTN, LS2_PTN, and LS3_PTN may be formed in substantially the same shape and at substantially the same position as the first to third lens structures LS1, LS2, and LS3, respectively, which have been described with reference to FIG. 6A.

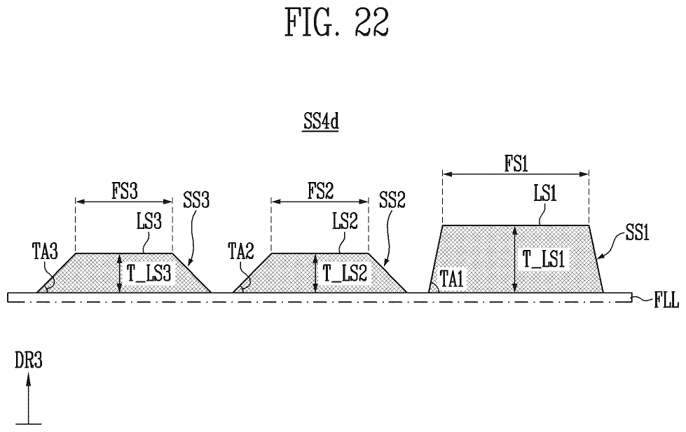

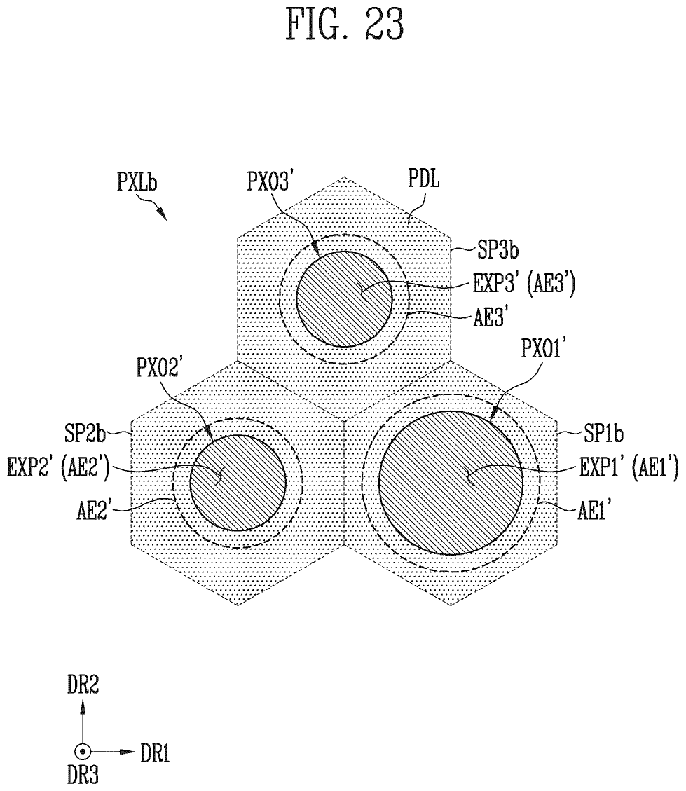

Referring to FIG. 22, after operation SS3d, an etch-back process for the entire surface may be performed (at operation SS4d). Accordingly, the first to third lens structures LS1, LS2, and LS3 may be provided.

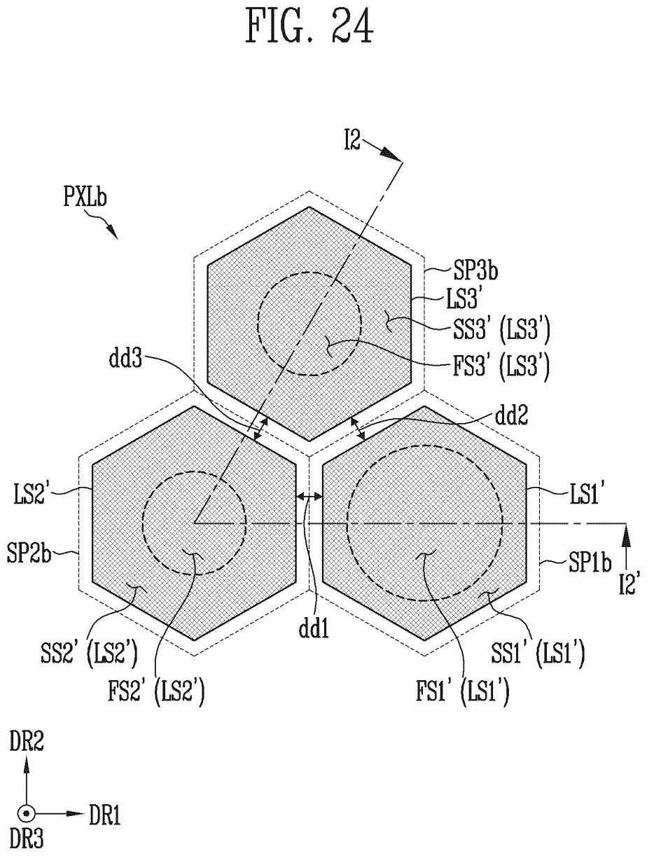

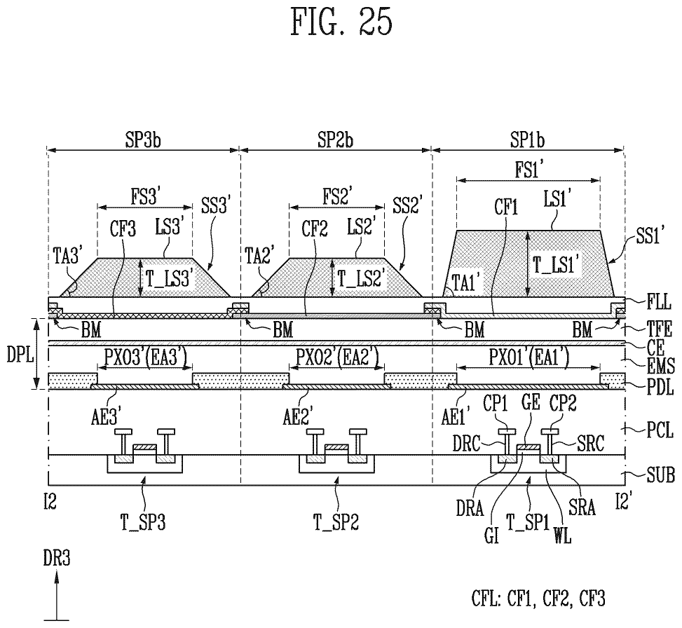

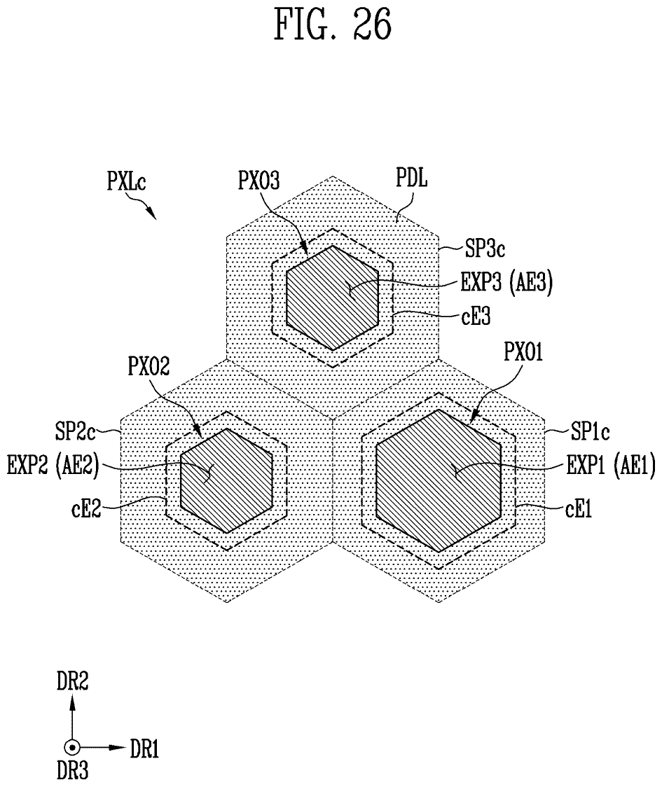

FIGS. 23 and 24 are plan views for describing one or more other embodiments of any one pixel included in the display panel of FIG. 3. FIG. 25 is a sectional view taken along the line I2-I2′ of FIG. 24.

Hereinafter, a pixel PXLb, and the first to third sub-pixels SP1b, SP2b, and SP3b included in the pixel PXLb, will be described, focusing on differences from the pixel PXLa described with reference to FIGS. 4 to 8 and the first to third sub-pixels SP1a, SP2a, and SP3a included in the pixel PXLa, and any omitted content will be covered by the aforementioned descriptions.

Referring to FIGS. 23 to 25, first to third pixel openings PXO1′, PXO2′, and PXO3′ that respectively expose portions of first to third anode electrodes AE1′, AE2′, and AE3′ may each have a circular shape in a plan view. Therefore, first to third exposed surfaces EXP1′, EXP2′, and EXP3′ of the first to third anode electrodes AE1′, AE2′, and AE3′ may each have a circular shape in a plan view.

A planar surface area of the first exposed surface EXP1′ may be greater than a planar surface area of the second exposed surface EXP2′, and also may be greater than a planar surface area of the third exposed surface EXP3′. The planar surface area of the second exposed surface EXP2′ may be substantially the same as the planar surface area of the third exposed surface EXP3′.

The first exposed surface EXP1′ may be an area corresponding to a first emission area EA1′ of a light-emitting element LD (refer to FIG. 2) of the first sub-pixel SP1b. The second exposed surface EXP2′ may be an area corresponding to a second emission area EA2′ of a light-emitting element LD of the second sub-pixel SP2b. The third exposed surface EXP3′ may be an area corresponding to a third emission area EA3′ of a light-emitting element LD of the third sub-pixel SP3b.

First to third lens structures LS1′, LS2′, and LS3′ may be located on the planarization layer FLL. The first to third lens structures LS1′, LS2′, and LS3′ may respectively overlap the first to third anode electrodes AE1′, AE2′, and AE3′.

The first lens structure LS1′ may include a first flat surface FS1′ and a first side surface SS1′ adjacent thereto. The second lens structure LS2′ may include a second flat surface FS2′ and a second side surface SS2′ adjacent thereto. The third lens structure LS3′ may include a third flat surface FS3′ and a third side surface SS3′ adjacent thereto.

The first to third flat surfaces FS1′, FS2′, and FS3′ may completely overlap the first to third exposed surfaces EXP1′, EXP2′, and EXP3′, respectively. In other words, the first to third flat surfaces FS1′, FS2′, and FS3′ may have planer shapes and planer surface areas corresponding to those of the first to third exposed surfaces EXP1′, EXP2′, and EXP3′, respectively.

In a cross-sectional view, a first thickness T_LS1′ of the first lens structure LS1′ may be greater than a second thickness T_LS2′ of the second lens structure LS2′, and may be greater than a third thickness T_LS3′ of the third lens structure LS3′. Furthermore, a second thickness T_LS2′ of the second lens structure LS2′ may be substantially the same as a third thickness T_LS3′ of the third lens structure LS3′.

A first taper angle TA1′ between the first side surface SS1′ and the upper surface of the planarization layer FLL may be greater than a second taper angle TA2′ between the second side surface SS2′ and the upper surface of the planarization layer FLL, and may also be greater than a third taper angle TA3′ between the third side surface SS3′ and the upper surface of the planarization layer FLL. The second taper angle TA2′ and the third taper angle TA3′ may be substantially the same as each other.

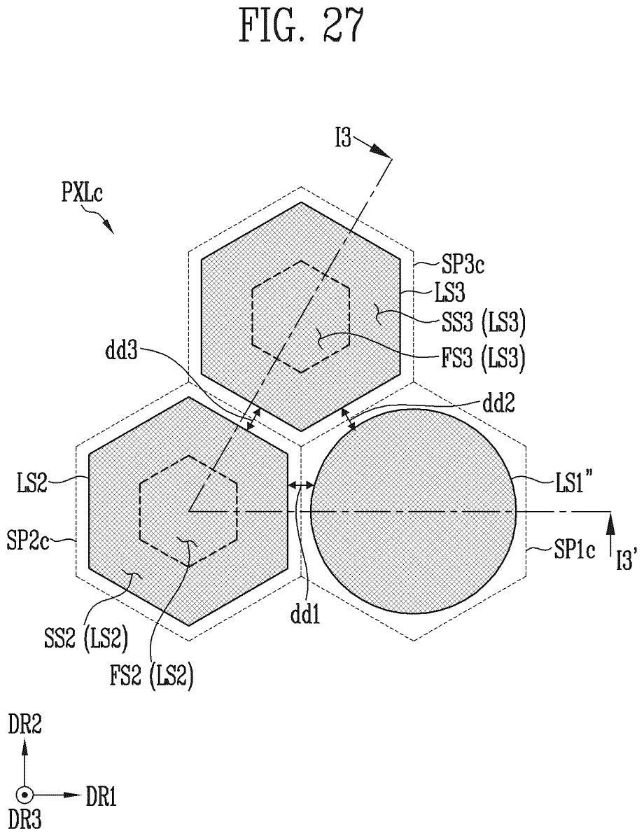

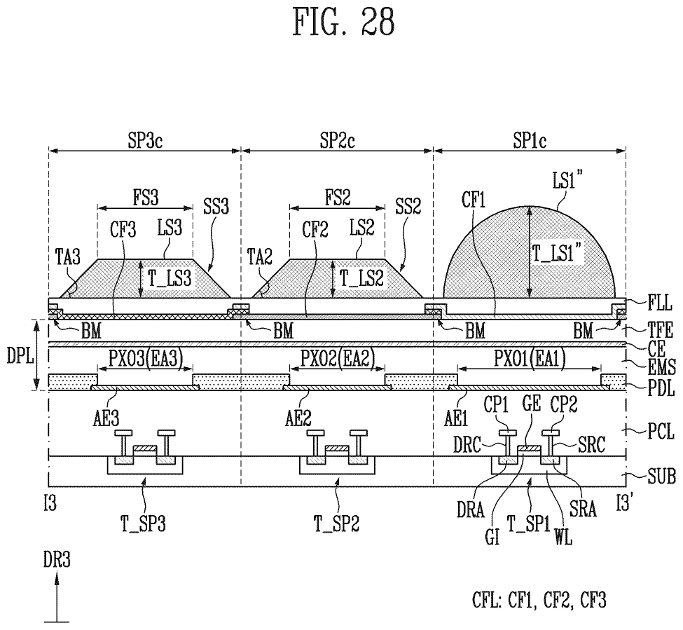

FIGS. 26 and 27 are plan views for describing one or more other embodiments of any one pixel included in the display panel of FIG. 3. FIG. 28 is a sectional view taken along the line I3-I3′ of FIG. 27.

Hereinafter, a pixel PXLc, and the first to third sub-pixels SP1c, SP2c, and SP3c included in the pixel PXLc, will be described, focusing on differences from the pixel PXLa described with reference to FIGS. 4 to 8 and the first to third sub-pixels SP1a, SP2a, and SP3a included in the pixel PXLa, and any omitted content will be covered by the aforementioned descriptions.

Referring to FIGS. 26 to 28, the first sub-pixel SP1c may include a first lens structure LS1′. Unlike the second and third lens structures LS2 and LS3, the first lens structure LS1′ may have a circular shape in a plan view, and may have a semicircular (or semielliptical) shape in a sectional view.

In this case, in a sectional view, a first thickness T_LS1′ from a lower surface of the first lens structure LS1′ to an uppermost point of the first lens structure LS1′ may be greater than the second thickness T_LS2 of the second lens structure LS2, and also may be greater than the third thickness T_LS3 of the third lens structure LS3.

As such, the first lens structure LS1′ may have various structures for improving the light output efficiency. Although FIGS. 26 to 28 describe one or more modified embodiments in which the shape of the first lens structure LS1′ differs from that of the first lens structure LS1 described with reference to FIGS. 4 to 8, the shapes of the second and third lens structure LS2 and LS3 may also be modified in various ways.

A display device according to an embodiment is applicable to various types of electronic devices. In an embodiment, an electronic device includes the above-described display device and may further include other modules or devices having additional functions in addition to the display device.

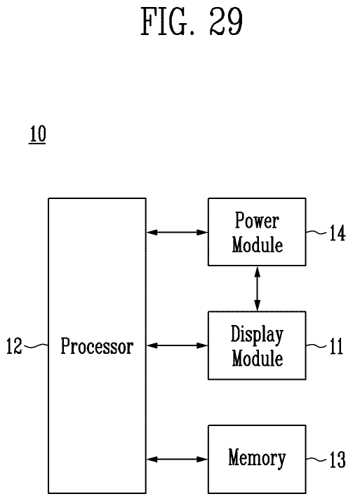

FIG. 29 is a block diagram of an electronic device according to an embodiment. Referring to FIG. 29, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in the electronic device 10 may be included in the display device and others may be provided separately from the display device. For example, the display module 11 is included in the display device, whereas the processor 12, the memory 13, and the power module 14 are not included in the display device and are instead provided separately in the electronic device 10.

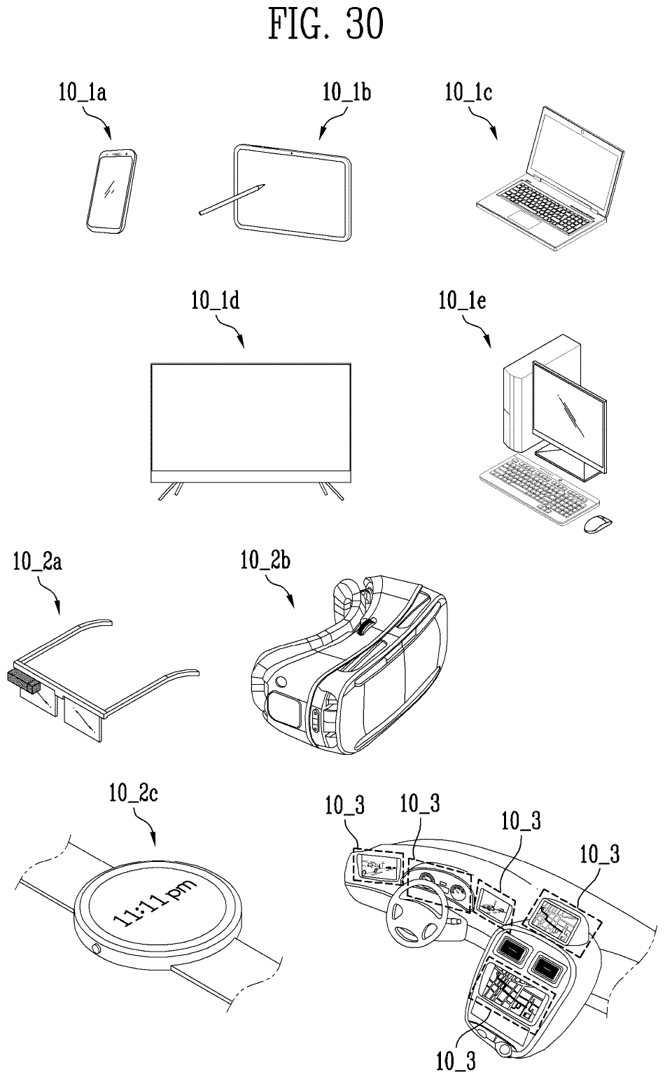

FIG. 30 shows schematic views of various embodiments of an electronic device.

Referring to FIG. 30, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In a display device in accordance with embodiments, a planar surface area of a first exposed surface of a first anode electrode may be greater than a planar surface area of a second exposed surface of a second anode electrode.

In this case, a first lens structure overlapping the first anode electrode may have a structure suitable for improving light output efficiency of a sub-pixel including the first anode electrode. For example, the first lens structure may have a relatively large thickness.

Consequently, the light output efficiency of the display device may be improved.

While embodiments have been described above, those skilled in the art will appreciate that various modifications, additions and substitutions are possible, without departing from the scope and spirit of the present disclosure claimed in the appended claims, with functional equivalents thereof to be included therein.

What is claimed is:

1. A display device comprising:
a first anode electrode and a second anode electrode spaced apart from each other;
a pixel-defining layer defining a second pixel opening overlapping a second exposed surface of the second anode electrode, and a first pixel opening overlapping a first exposed surface of the first anode electrode having a planar surface area that is greater than a planar surface area of the second exposed surface;
a cathode electrode facing the first anode electrode and the second anode electrode;
an emission structure between the cathode electrode and the first exposed surface and the second exposed surface; and
a first lens structure and a second lens structure above the cathode electrode, respectively overlapping the first anode electrode and the second anode electrode, and having a trapezoidal shape in a sectional view in which a length of a top side is less than a length of a bottom side, a first thickness of the first lens structure being greater than a second thickness of the second lens structure in a sectional view.

2. The display device according to claim 1, wherein upper surfaces of the first lens structure and the second lens structure are flat.

3. The display device according to claim 2, wherein, in a plan view, the upper surfaces of the first lens structure and the second lens structure completely overlap the first exposed surface and the second exposed surface, respectively.

4. The display device according to claim 1, wherein the first exposed surface and the second exposed surface have a circular or N-sided polygonal shape in a plan view, N being a natural number of 4 or more.

5. The display device according to claim 4, wherein the first lens structure and the second lens structure have an M-sided polygonal shape in a plan view, M being equal to N.

6. The display device according to claim 5, wherein the first lens structure and the second lens structure have a substantially identical planar surface area.

7. The display device according to claim 1, further comprising:
a third anode electrode spaced apart from the first anode electrode and the second anode electrode; and
a third lens structure above the cathode electrode to overlap the third anode electrode, and having a trapezoidal shape in which a length of a top side is less than a length of a bottom side in a sectional view,
wherein the pixel-defining layer further defines a third pixel opening overlapping a third exposed surface of the third anode electrode.

8. The display device according to claim 7, wherein the planar surface area of the second exposed surface is substantially identical to a planar surface area of the third exposed surface, and
wherein the second thickness of the second lens structure is substantially identical to a third thickness of the third lens structure in a sectional view.

9. The display device according to claim 7, wherein, in a plan view, a first shortest distance between the first lens structure and the second lens structure, a second shortest distance between the first lens structure and the third lens structure, and a third shortest distance between the second lens structure and the third lens structure are substantially identical.

10. The display device according to claim 7, further comprising a color filter layer between the cathode electrode and the first lens structure, the second lens structure, and the third lens structure.

11. The display device according to claim 10, wherein the color filter layer comprises a blue color filter overlapping the first exposed surface, a green color filter overlapping the second exposed surface, and a red color filter overlapping the third exposed surface.

12. The display device according to claim 1, wherein a surface area of a side surface of the first lens structure is greater than a surface area of a side surface of the second lens structure.

13. A display device comprising:
a first anode electrode and a second anode electrode spaced apart from each other;
a pixel-defining layer defining a second pixel opening overlapping a second exposed surface of the second anode electrode and a first pixel opening overlapping a first exposed surface of the first anode electrode having a planar surface area that is greater than a planar surface area of the second exposed surface;
a cathode electrode facing the first anode electrode and the second anode electrode;
an emission structure between the cathode electrode and the first exposed surface and the second exposed surface;
a second lens structure above the cathode electrode, overlapping the second anode electrode, and having a trapezoidal shape in a sectional view in which a length of a top side is less than a length of a bottom side; and
a first lens structure above the cathode electrode, overlapping the first anode electrode, and having a semicircular or semielliptical shape in a sectional view having a first thickness from a lower surface of the first lens structure to an uppermost point of the first lens structure that is greater than a second thickness of the second lens structure.

14. The display device according to claim 13, wherein the first exposed surface and the second exposed surface have a circular or N-sided polygonal shape in a plan view, N being a natural number of 4 or more.

15. The display device according to claim 14, wherein the first lens structure has a circular shape in a plan view, and
wherein the second lens structure has an M-sided polygonal shape in a plan view, M being equal to N.

16. The display device according to claim 13, further comprising:
a third anode electrode spaced apart from the first anode electrode and the second anode electrode; and
a third lens structure above the cathode electrode to overlap the third anode electrode, and having a trapezoidal shape in which a length of a top side is less than a length of a bottom side in a sectional view, and
wherein the pixel-defining layer further defines a third pixel opening overlapping a third exposed surface of the third anode electrode.

17. The display device according to claim 16, wherein the planar surface area of the second exposed surface is substantially identical to a planar surface area of the third exposed surface, and
wherein the second thickness of the second lens structure is substantially identical to a third thickness of the third lens structure in a sectional view.

18. The display device according to claim 16, wherein, in a plan view, a first shortest distance between the first lens structure and the second lens structure, a second shortest distance between the first lens structure and the third lens structure, and a third shortest distance between the second lens structure and the third lens structure are substantially identical.

19. The display device according to claim 16, further comprising a color filter layer between the cathode electrode and the first lens structure, the second lens structure, and the third lens structure, wherein
the color filter layer comprises a blue color filter overlapping the first exposed surface, a green color filter overlapping the second exposed surface, and a red color filter overlapping the third exposed surface.

20. An electronic device comprising:
a processor to provide an image data; and
a display device to display an image based on the image data, the display device comprising:
a first anode electrode and a second anode electrode spaced apart from each other;
a pixel-defining layer defining a second pixel opening overlapping a second exposed surface of the second anode electrode, and a first pixel opening overlapping a first exposed surface of the first anode electrode having a planar surface area that is greater than a planar surface area of the second exposed surface;
a cathode electrode facing the first anode electrode and the second anode electrode;
an emission structure between the cathode electrode and the first exposed surface and the second exposed surface; and
a first lens structure and a second lens structure above the cathode electrode, respectively overlapping the first anode electrode and the second anode electrode, and having a trapezoidal shape in a sectional view in which a length of a top side is less than a length of a bottom side, a first thickness of the first lens structure being greater than a second thickness of the second lens structure in a sectional view.
